(19) United States
(12) Patent Application Publication
(10) Pub. No.: US 2026/0162735 A1
(43) Pub. Date: Jun. 11, 2026

(54) NON-VOLATILE MEMORY WITH DIFFERENT READ AND WRITE CLOCKS

(71) Applicant: STMicroelectronics International N.V., Geneva (CH)

(72) Inventors: Olivier ROULENQ, Saint Egreve (FR); Philippe GENDRIER, Grenoble (FR); Benoit BUTAYE, Meylan (FR); David JACQUET, Vaulnaveys Le Haut (FR)

(73) Assignee: STMicroelectronics International N.V., Geneva (CH)

(21) Appl. No.: 19/412,140

(22) Filed: Dec. 8, 2025

(30) Foreign Application Priority Data
Dec. 9, 2024 (EP) 24315563.7

(51) Int. Cl. G11C 16/32; G11C 16/10; G11C 16/26

(52) U.S. Cl. CPC G11C 16/32; G11C 16/102; G11C 16/26

(57) ABSTRACT

An electronic device includes a non-volatile memory. Operations for reading data from the memory are performed in response to a first clock signal. Operations for writing data to the memory are performed in response to a second clock signal which is different from the first clock signal. The first clock signal is generated by an oscillation circuit of the electronic device, and the second clock signal is generated external to the electronic device (for example through a communications interface).

### PRIORITY CLAIM

This application claims the priority benefit of European Application for Patent No. 24315563.7, filed on December 9, 2024, the content of which is hereby incorporated by reference in its entirety to the maximum extent allowable by law.

### TECHNICAL FIELD

The present disclosure generally concerns electronic systems and devices and, in particular, the management of data storage by the use of one or more memories in these systems and devices. The present disclosure more particularly concerns the operation of a non-volatile memory.

### BACKGROUND

Memories are electronic devices, or circuits, configured to store information. Two main operations can be implemented by a memory, a write operation, enabling to store data into the memory, and a read operation, enabling to retrieve the data written into the memory. Memory control circuits are generally used to implement these operations.

It would be desirable to be able to improve, at least partly, certain aspects of known memories and memory control circuits.

There exists a need for higher-performance memories, and more specifically for higher-performance non-volatile memories.

There exists a need for higher-performance memory control circuits.

There exists a need for memory control circuits having a smaller bulk.

There exists in particular a need for electronic devices having a smaller bulk and comprising such a memory and a circuit for controlling this memory.

There is a need to overcome all or part of the disadvantages of known memories and of their known control circuits.

### SUMMARY

An embodiment provides a device comprising a circuit for controlling a memory configured to use clock signals of different frequencies for write and read operations.

An embodiment provides an electronic device comprising a non-volatile memory, wherein a first clock signal is configured to be used for operations of reading from said memory, and a second clock signal, different from the first clock signal, is configured to be used for operations of writing to said memory.

Another embodiment provides a method of using a non-volatile memory of an electronic device, wherein a first clock signal is configured to be used for operations of reading from said memory, and a second clock signal, different from the first clock signal, is configured to be used for operations of writing to said memory.

According to an embodiment, said non-volatile memory is an array of one-time programmable memory cells.

According to an embodiment, said second clock signal is more precise than said first clock signal.

According to an embodiment, the frequency of said second clock signal is more precise than the frequency of said first clock signal.

According to an embodiment, said first clock signal is supplied by a ring oscillator included in said device.

According to an embodiment, said second clock signal is supplied by a circuit external to said device and different from said ring oscillator.

According to an embodiment, said circuit external to said device is a communication interface external to said device supplying said second clock signal via a circuit for controlling said memory.

According to an embodiment, said communication interface external to said device uses a communication protocol selected from the following non-exhaustive group: the I2C protocol, the UART protocol, the SPI protocol, the JTAG protocol, and the RFFE protocol.

According to an embodiment, said second clock signal may have a dynamically-controllable frequency.

According to an embodiment, said device further comprises said circuit for controlling said memory configured to control said read and write operations.

According to an embodiment, said circuit for controlling said memory comprises a single state machine configured to control said read and write operations.

According to an embodiment, said circuit for controlling said memory comprises a first state machine configured to control said read operations, and a second state machine configured to control said write operations.

According to an embodiment, the state machine(s) are configured to receive a dynamic frequency control signal.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows, schematically, an embodiment of an electronic device comprising a memory and a circuit for controlling the memory;

FIG. 2 shows, schematically, a first example of embodiment of a portion of the control circuit of FIG. 1;

FIG. 3 shows, schematically, a second example of embodiment of a portion of the control circuit of FIG. 1;

FIG. 4 shows timing diagrams illustrating the operation of the embodiment of FIG. 1; and

FIG. 5 shows other timing diagrams illustrating the operation of the embodiment of FIG. 1.

### DETAILED DESCRIPTION

The same elements have been designated by the same references in the various figures. In particular, structural and/or functional elements common to the different embodiments may have the same references and may have identical structural, dimensional and material properties.

For the sake of clarity, only those steps and elements that are useful for understanding the described embodiments have been shown and are described in detail.

Unless specified otherwise, when reference is made to elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as the terms "front", "back", "top", "bottom", "left", "right", etc., or relative position qualifiers, such as the terms "top", "bottom", "upper", "lower", etc., or orientation qualifiers, such as "horizontal", "vertical", etc., reference is made unless otherwise specified to the orientation of the drawings.

Unless specified otherwise, the expressions "about", "approximately", "substantially", and "in the order of" signify plus or minus 10% or 10°, preferably of plus or minus 5% or 5°.

The embodiments described hereafter provide a solution to a problem affecting electronic devices comprising non-volatile memories, such as memory arrays comprising one-time programmable memory cells. Such memories are generally associated with a ring oscillator delivering a precise clock signal enabling to synchronize read and write operations of these memory cells. A disadvantage is that a ring oscillator is associated only with one or more memory arrays, which may raise bulk, power consumption, and cost issues.

The embodiments described hereafter thus provide a solution which replaces a clock signal supplied by a ring oscillator dedicated to one or more memories by two clock signals supplied by separate sources. A first clock signal is intended to only synchronize operations of reading of data stored in the memory, and is supplied by a ring oscillator shared by other circuits of the electronic device comprising the memory array. A second clock signal is intended to only synchronize operations of writing data to the memory and is supplied by an external circuit, for example an external ring oscillator, to the electronic device comprising the memory array. This circuit may, for example, form part of a test tool used in a factory during the putting into service of the electronic device. Indeed, when the non-volatile memory is a memory array comprising one-time programmable (OTP) memory cells, data are often programmed during or just after the manufacturing of the electronic device comprising the memory in the factory.

More particularly, the first and second clock signals have different characteristics, apart from their source. In particular, the first clock signal does not necessarily need to be very precise, while the second clock signal needs to be very precise. Indeed, a reliable non-volatile memory needs to offer reliable and secure means for storing data that must remain unchanged throughout the life of the electronic device. To achieve a reliable storage, the voltage used for writing needs to be finely controlled, as well as the writing time to definitively burn the fuse, used as the memory cell for the memory. This implies the need for a high precision for the second clock signal. This constraint does not exist for read operations during the life of the electronic device, whereby the first clock signal does not necessarily need to be very precise. According to an example, a precision of the frequency of the second clock signal will be accepted to a maximum of 10%, while for the frequency of the first clock signal, a precision to 70% remains acceptable. According to an example, a pulse of a programming signal may have a 1-ms width with a precision of plus or minus 10%, while a pulse of the read signal may have a 155-µs width with a precision of plus or minus 70%, for example 93%.

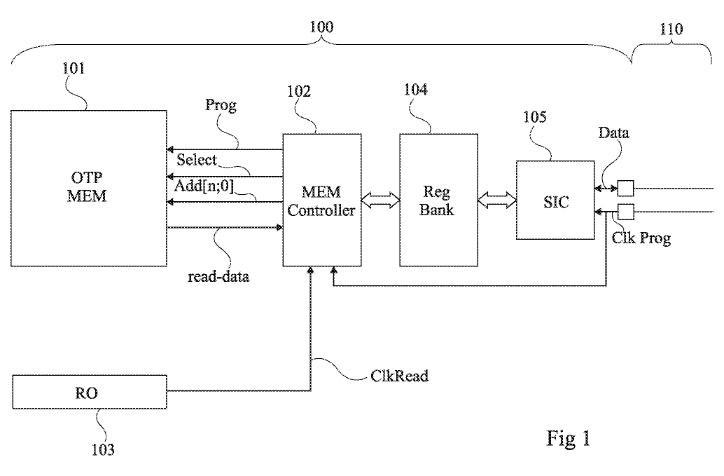

Further, the second clock signal may exhibit a dynamic control of its frequency, as more particularly described in relation with FIGS. 1 to 5.

Further, the embodiments described hereafter are particularly configured to be used in devices coupled to antennas, such as interface circuits, for example, circuits which receive and/or transmit data to an antenna.

More generally, the above-described embodiments are particularly configured to be used in any type of industrial market where the use of a non-volatile memory is required. More particularly, such an electronic device comprising a non-volatile memory may be intended for: the automotive industry, for example in the field of automotive electrification or in the field of advanced driver assistance systems (ADAS); the industrial sector, for example in the field of green energy, in the field of infrastructure electrification, of the Internet of Things (IoT) and of smart homes, where electricity and energy consumption and data exchange are key elements; the personal electronics industry, for example in the field of mobile telephony and of the Internet of Things (IoT), as well as in high-speed interfaces; and the industry of communications equipment, computers and peripherals, for example in the field of infrastructure and data centers, and in the field of low earth orbit (LEO) satellites.

FIG. 1 shows, very schematically and in the form of blocks, an embodiment of an electronic device 100.

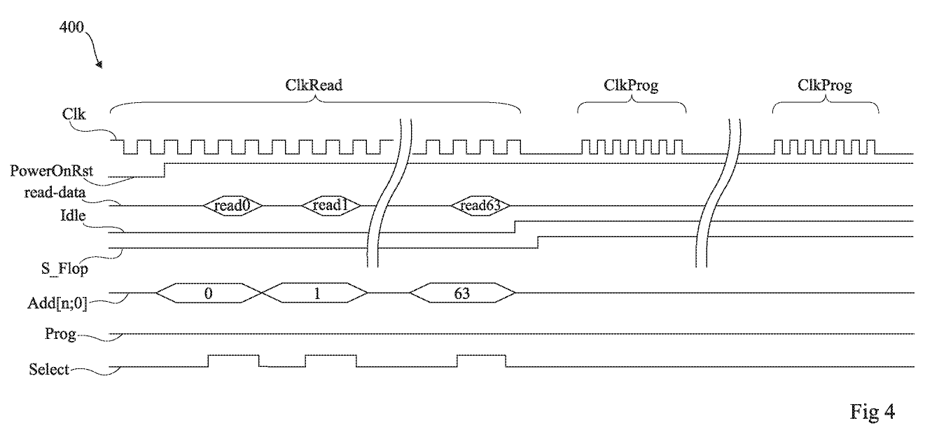

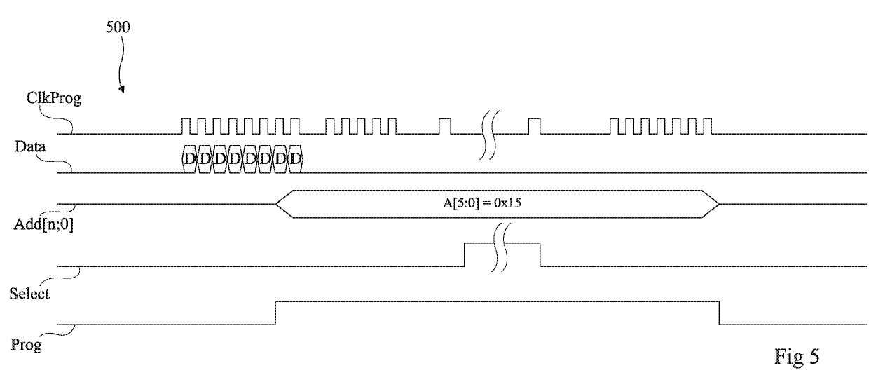

According to an embodiment, device 100 comprises a non-volatile memory 101 (one-time programmable (OTP) MEM). According to a preferred embodiment, non-volatile memory 101 is a memory array comprising one-time programmable memory cells. According to an example, this memory 101 is configured to receive programming signals Prog, Add[n;0], and Select, and to supply, at least, a data read signal Read-data. Programming signals Prog, Add[n;0], and Select are described in more detail in relation with FIGS. 4 and 5.

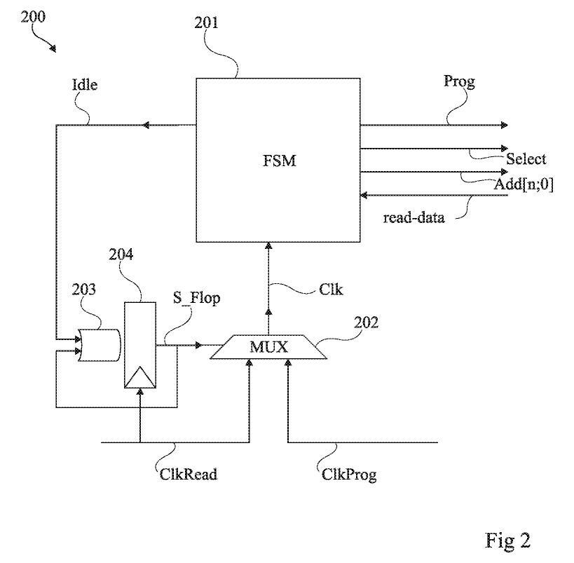

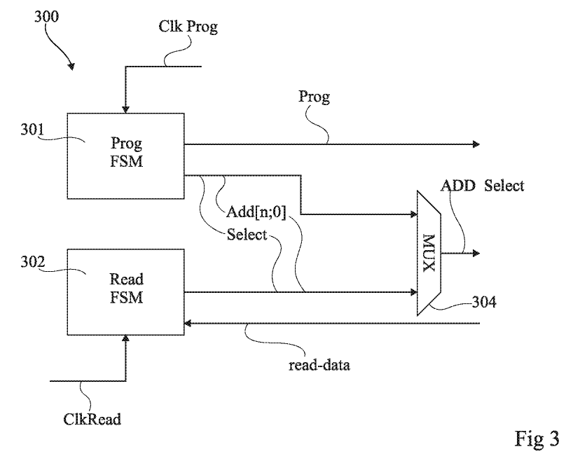

According to an embodiment, device 100 further comprises a circuit 102 (MEM Controller) for controlling memory 101. Two example embodiments of parts of this control circuit 102 are detailed in relation with FIGS. 2 and 3. According to an example, control circuit 102 is configured to supply memory 101 with programming signals Prog Add[n;0], and Select, and to receive, from memory 101, data read signal Read-data.

Further, and according to an embodiment, control circuit 102 is configured to receive two different clock signals ClkRead and ClkProg, that is, clock signals ClkRead and ClkProg which have different frequencies. According to an embodiment, clock signal ClkRead is configured to be used for the execution of operations for reading data stored in memory 101. More particularly, clock signal ClkRead is, according to an embodiment, configured to be used by the control circuit 102 to clock operations for reading data stored in memory 101. According to an embodiment, clock signal ClkProg is configured to be used for the execution of operations for writing data to memory 101. More particularly, clock signal ClkProg is, according to an embodiment, configured to be used by control circuit 102 to clock operations for writing data to memory 101, that is, for example to generate programming signal Prog.

According to an embodiment, clock signal ClkRead is less precise than clock signal ClkProg. More particularly, the frequency of clock signal ClkRead is less precise than the frequency of clock signal ClkProg. This means that clock signal ClkProg is more reliable than clock signal ClkRead. Further, the frequency of clock signal ClkProg is provided by circuit 110 external to device 100, whereby clock signal ClkProg can exhibit a dynamic control of its frequency. This is described in more detail in relation with FIG. 5.

According to an example, device 100 further comprises a ring oscillator 103 configured to supply clock signal ClkRead. According to an embodiment, ring oscillator 103 is used by other circuits of device 100 and is not only dedicated to the implementation of operations for reading data stored in memory 101. According to an example, oscillator 103 is configured to supply a periodic signal having a wide frequency range and requiring no calibration. According to a specific example, oscillator 103 is configured to supply a periodic signal having a frequency in the range from 6 MHz to 15 MHz.

According to an embodiment, clock signal ClkProg is generated by circuit 110, different from oscillator 103. According to an embodiment, clock signal ClkProg is generated by circuit 110 external to device 100. According to a specific example, clock signal ClkProg is generated by a test circuit used in a factory, and operations for writing data to memory 101 are only performed at the putting into service of device 100. According to an example, circuit 110 is a communication interface external to device 100. According to an example, this communication interface external to said device 100 is configured to use a communication protocol selected from the following non-exhaustive group: the I2C protocol, the UART protocol, the SPI protocol, the JTAG protocol, and the RFFE protocol.

According to an example, device 100 may further comprise a register bank 104 (Reg Bank) 104 configure to store data. According to an example, register bank 104 may be used as a buffer during the implementation of data read and/or write operations.

According to an example, device 100 further comprises an interface circuit (SIC) 105 configured to exchange data with register bank 104. According to a specific example, interface circuit 105 is a serial interface controller (SIC). According to an example, circuit 105 is configured to receive or transmit a general data signal Data from device 100, which signal Data may be, for example, used to transmit data read from memory 101 and/or to write data into memory 101, for example using register bank 104. According to an example, circuit 102 may be configured to receive clock signal ClkProg.

An advantage of this electronic device is that it only comprises the ring oscillator 103 generating clock signal ClkRead, which is not necessarily a precise signal. Ring oscillator 103 is thus not a very bulky component. On the other hand, clock signal ClkProg is necessarily supplied by a rather bulky circuit, since this signal ClkProg needs to be precise. Thus, the use of such an embodiment enables to obtain a less bulky device 100 as the ClkProg signal generation circuit is “off chip”. According to an example, clock signal ClkProg may be the same as that of serial interface 105, which enables to decrease the cost of the package or to use a dedicated pin. According to another example, clock signal ClkProg may be supplied on a pin exclusively dedicated thereto.

FIG. 2 shows, very schematically and in the form of blocks, a first preferred example of embodiment of a portion 200 of the control circuit 102 described in relation with FIG. 1.

According to an embodiment, portion 200 comprises a finite state machine 201 (FSM) configured to control the data write and read operations of the memory 101 described in relation with FIG. 1.

For this purpose, portion 200 is configured to receive the clock signals ClkProg and ClkRead described in relation with FIG. 1, and to supplying the programming signals Prog, Select, and Add[n;0] also described in relation with FIG. 1.

According to an example, portion 200 further comprises a multiplexer 202 (MUX), an OR-type logic gate 203, and a flip-flop 204. A first terminal of multiplexer 202 is configured to receive clock signal ClkProg, and a second terminal of multiplexer 202 is configured to receive clock signal ClkRead. An output terminal of multiplexer 202 is configured to supply the state machine with a clock signal Idle based on clock signals ClkRead and ClkProg. A control terminal of multiplexer 202 is configured to receive information, delivered by a signal S_Flop, from an output terminal of flip-flop 204. A clock terminal of the flip-flop is configured to receive clock signal ClkRead. An input terminal of flip-flop 204 is coupled, preferably connected, to an output terminal of gate 203. A first input terminal of gate 202 is configured to receive a synchronization signal Idle output from state machine 201, and a second input terminal of gate 202 is coupled, preferably connected, to the output terminal of flip-flop 204.

FIG. 3 shows, very schematically and in the form of blocks, a second example of embodiment of a portion 300 of the control circuit 102 described in relation with FIG. 1.

According to an embodiment, portion 300 comprises two finite state machines 301 (Prog FSM) and 302 (Read FSM) configured to control operations for writing data to and reading data from the memory 101 described in relation with FIG. 1. More particularly, state machine 301 (Prog FSM) is configured to control operations for writing data to the memory 101 described in relation with FIG. 1, and receives, for this purpose, clock signal ClkProg. State machine 302 (Read FSM) is configured to control operations of reading data stored in memory 101, and receives, for this purpose, clock signal ClkRead and signal read-data.

According to an example, state machine 301 is configured to supply programming signal Prog to a memory of the type of the memory 101 described in relation with FIG. 1.

According to an example, portion 300 further comprises a multiplexer 304 (MUX) configured to supply control signals ADD and Select to a memory. For this purpose, the multiplexer receives, on a first input terminal, an output of state machine 301 and, on a second input terminal, an output of state machine 302. According to an example, the first input terminal of multiplexer 304 receives control signals Add[n;0] and Select from state machine 301, and the second input terminal of multiplexer 304 receives control signals Add[n;0] and Select from state machine 302.

FIG. 4 shows timing diagrams 400 illustrating the operation of the implementation of an operation of data reading and writing from and into the memory 101 of the device 100 described in relation with FIG. 1.

Timing diagrams 400 comprise: a timing diagram of the signal Clk described in relation with FIGS. 2; a timing diagram of a signal PowerOnRst for powering up device 100; a timing diagram of the signal read-data described in relation with FIG. 1; a timing diagram of the signal Idle described in relation with FIG. 2; a timing diagram of an output signal S_Flop of the flip-flop 203 of FIG. 2; a timing diagram of the control signal Add[n;0] described in relation with FIG. 1; a timing diagram of the control signal Prog described in relation with FIG. 1; and a timing diagram of the control signal Select described in relation with FIG. 1.

According to an example, signal Add[n;0] is used to select the memory cell of the memory into which a write operation is desired. According to an example, signal Prog is used to select the operational mode of the memory (reading if it is in the low state or writing if it is in the high state). According to an example, signal Select is a selection signal which delivers the activation time required to perform a reliable write operation or to reliably return data read from the memory.

During a data read phase, device 100 needs to be powered up, whereby signal PowerOnRst is in a high state. Further, the clock signal to be taken into account is clock signal ClkRead, whereby, during a read phase, signal Clk exhibits oscillations with a frequency equal to the frequency of clock signal ClkRead. This frequency being the default frequency used by device 100, signals Idle and S_Flop are also in low states. According to an example, at the end of the read phase, the state machine is made inactive by signal Idle. In the case of the circuit of FIG. 2, this information is stored in flip-flop 204, which enables to select clock signal ClkProg until the entire device is powered down. According to an example, the signal Select used for readings is generated by using clock signal ClkRead.

During a data write phase, device 100 needs to be powered up, whereby signal PowerOnRst is in a high state. Further, the clock signal to be taken into account is clock signal ClkProg, whereby, during a write phase, signal Clk exhibits oscillations with a frequency equal to the frequency of clock signal ClkProg. Signals Idle and S_Flop are in high states to indicate to take into account the frequency of signal ClkProg.

FIG. 5 shows timing diagrams 500 illustrating in more detail the operation of the implementation of a data write operation in the memory 101 of the device 100 described in relation with FIG. 1.

Timing diagrams 500 comprise: a timing diagram of the signal ClkProg described in relation with FIG. 1; a representation of a data signal Data received from, for example, interface circuit 105; a representation of a programming signal Add[n;0] used as a memory cell selection signal; a timing diagram of the programming signal Select described in relation with FIG. 4; a timing diagram of the programming signal Prog described in relation with FIG. 1.

To implement an operation of bit-by-bit data writing to the memory, clock signal Clk is based on clock signal ClkProg. The state machine is configured to make write states agnostic to the times required for writing to the memory, that is, for example, to burn out the fuses forming the memory cells in the memory. By dynamically controlling the frequency of external clock ClkProg, different programming times can be achieved. It is thus possible, after the circuit manufacturing, to change these times in order to overcome a reliability problem. The programming time is defined as a multiple of the frequency of signal ClkProg. According to an example, this programming time is defined by the states of a circuit, for example, a state machine, by performing a dynamic frequency control.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. An electronic device, comprising:
a non-volatile memory;
a circuit configured to apply a clock signal to the non-volatile memory;
wherein said circuit applies a first clock signal to the non-volatile memory for use during operations for reading data from said non-volatile memory; and
wherein said circuit applies a second clock signal, different from the first clock signal, to the non-volatile memory during operations for writing data to said non-volatile memory.

2. The electronic device according to claim 1, wherein said non-volatile memory comprises an array of one-time programmable memory cells.

3. The electronic device according to claim 1, wherein said first clock signal has a first precision, wherein said second clock signal has a second precision, and wherein the second precision is more precise than the first precision.

4. The electronic device according to claim 1, wherein said first clock signal has a first frequency, wherein said second clock signal has a second frequency, and wherein the second frequency is more precise than the first frequency.

5. The electronic device according to claim 1, further comprising a ring oscillator configured to supply said first clock signal.

6. The electronic device according to claim 5, wherein said second clock signal is supplied by a circuit external to said electronic device and different from said ring oscillator.

7. The electronic device according to claim 6, wherein said circuit external to said electronic device is a communication interface external to said device supplying said second clock signal via a circuit for controlling said non-volatile memory.

8. The electronic device according to claim 7, wherein said communication interface external to said electronic device uses a communication protocol selected from the group consisting of: an I2C protocol, a UART protocol, an SPI protocol, a JTAG protocol, and an RFFE protocol.

9. The electronic device according to claim 1, wherein said second clock signal has a dynamically-controllable frequency.

10. The electronic device according to claim 1, further comprising a control circuit configured to control said non-volatile memory to perform read and write operations.

11. The electronic device according to claim 10, wherein said control circuit comprises a finite state machine configured to control said read and write operations.

12. The electronic device according to claim 10, wherein said control circuit comprises a first finite state machine configured to control said read operations, and a
second finite state machine configured to control said write operations.

13. The electronic device according to claim 12, wherein the second finite state machine is configured to receive a dynamic frequency control signal for controlling a frequency of said second clock signal.

14. A method of using a non-volatile memory of an electronic device, comprising:
applying a first clock signal to the non-volatile memory during operations for reading data from said non-volatile memory; and
applying a second clock signal, different from the first clock signal, to the non-volatile memory during operations for writing data to said memory.

15. The method according to claim 14, wherein said non-volatile memory is an array of one-time programmable memory cells.

16. The method according to claim 14, wherein said second clock signal is more precise than said first clock signal.

17. The method according to claim 14, wherein a frequency of said second clock signal is more precise than a frequency of said first clock signal.

18. The method according to claim 14, further comprising:
supplying said first clock signal using a ring oscillator included in said electronic device;
supplying said second clock signal using a circuit external to said electronic device.

19. The method according to claim 18, wherein said circuit external to said device is a communication interface using a communication protocol selected from the group consisting of: an I2C protocol, a UART protocol, an SPI protocol, a JTAG protocol, and an RFFE protocol.

20. The method according to claim 14, further comprising dynamically-controlling a frequency of said second clock signal.
